(19) United States
(12) Patent Application Publication
(10) Pub. No.: US 2023/0056817 A1
(43) Pub. Date: Feb. 23, 2023

(54) Cryogenic System with Optical Fiber Delivering Power and Transferring Data

(71) Applicant: The United States of America, as represented by the Secretary of the Navy, San Diego, CA (US)

(72) Inventors: Brad Chun-Ting Liu, San Diego, CA (US); Sergio A. Montoya, Chula Vista, CA (US); Saurabh Sharma, San Diego, CA (US); Carlos Torres, JR., San Diego, CA (US); Marico C. de Andrade, San Diego, CA (US); Michael C. O'Brien, San Diego, CA (US)

(21) Appl. No.: 17/408,232

(22) Filed: Aug. 20, 2021

(51) Int. Cl. H01L 39/16; H04B 10/80; H04B 10/40

(52) U.S. Cl. CPC H01L 39/16; H04B 10/808; H04B 10/40

(57) ABSTRACT

A cryogenic system cools and operates cryogenic electronics. The cryogenic system includes a cryogenic stage or multiple cryogenic stages for cooling the cryogenic electronics to an operational cryogenic temperature. The cryogenic stage or stages transfer heat from the cryogenic electronics to an ambient environment. An optical fiber or multiple optical fibers deliver an operational power from the ambient environment to the cryogenic electronics and transfer communication data between the cryogenic electronics and the ambient environment. Preferably, the only connection delivering any power from the ambient environment to the cryogenic electronics or transferring any data from the cryogenic electronics to the ambient environment is the optical fiber or fibers, such that the cryogenic system does not include any electrically conductive wires spanning between the ambient environment and the cryogenic electronics.

### FEDERALLY-SPONSORED RESEARCH AND DEVELOPMENT

The United States Government has ownership rights in this invention. Licensing and technical inquiries may be directed to the Office of Research and Technical Applications, Naval Information Warfare Center Pacific, Code 72120, San Diego, Calif., 92152; voice (619) 553-5118; ssc_pac_t2@navy.mil. Reference Navy Case Number 110406.

### BACKGROUND OF THE INVENTION

Superconducting devices offer capabilities not available to devices operating at room temperature. However, superconductive devices have the drawback that energy is needed to cool the superconductive devices below a critical temperature for achieving superconductivity. This cooling energy expenditure is not needed in devices operating at room temperature, and this cooling energy expenditure often greatly exceeds the energy needed to power the closest corresponding device operating at room temperature. There is a general need to improve the operating efficiency of superconductive devices.

### SUMMARY

A cryogenic system cools and operates cryogenic electronics. The cryogenic system includes a cryogenic stage or multiple cryogenic stages for cooling the cryogenic electronics to an operational cryogenic temperature. The cryogenic stage or stages transfer heat from the cryogenic electronics to an ambient environment. An optical fiber or multiple optical fibers deliver an operational power from the ambient environment to the cryogenic electronics and transfer communication data between the cryogenic electronics and the ambient environment. Preferably, the only connection delivering any power from the ambient environment to the cryogenic electronics or transferring any data from the cryogenic electronics to the ambient environment is the optical fiber or fibers, such that the cryogenic system does not include any electrically conductive wires spanning between the ambient environment and the cryogenic electronics.

### BRIEF DESCRIPTION OF THE DRAWINGS

Throughout the several views, like elements are referenced using like references. The elements in the figures are not drawn to scale and some dimensions are exaggerated for clarity.

FIG. 1 is a block diagram of a cryogenic system with optical fibers delivering power and transferring data in accordance with an embodiment of the invention.

FIG. 2 is a block diagram of a cryogenic system with an optical fiber delivering power and transferring data in accordance with an embodiment of the invention.

FIG. 3A-E are each a schematic diagram of a cryogenic system with an optical fiber and superconducting electrical wires delivering power in accordance with an embodiment of the invention.

### DETAILED DESCRIPTION OF EMBODIMENTS

The disclosed systems below may be described generally, as well as in terms of specific examples and/or specific embodiments. For instances where references are made to detailed examples and/or embodiments, it should be appreciated that any of the underlying principles described are not to be limited to a single embodiment, but may be expanded for use with any of the other methods and systems described herein as will be understood by one of ordinary skill in the art unless otherwise stated specifically.

Two main problems of superconducting devices are the heat leakage through metallic conductors connecting the cryogenic and ambient environments, and the limited data bandwidth of such metallic conductors.

The heat leakage stems from the high thermal conduction of metallic conductors, such as metal or transition metal wires, spanning between the cryogenic environment at a cryogenic temperature and the ambient environment at room temperature, and the generation of heat from resistive losses in the metallic conductors carrying electrical current between the ambient and cryogenic environments. In the related art, such metallic conductors are necessary to supply power generated in the ambient environment to the superconducting devices in the cryogenic environment, and to transfer data between the ambient and cryogenic environments. Thin metal wires reduce the thermal conduction, but increase the resistive losses for those metal wires supplying power. To offset this heat leakage through the metallic conductors, more energy must be expended in the cryogenic stages for cooling the superconducting devices to the operational cryogenic temperature. This energy expenditure dramatically limits the operating efficiency of superconductive devices in the related art.

Certain superconducting devices are excellent electromagnetic sensors, enabling the decoding of data encoded in extremely high frequency signals. Such extremely high frequency signals encode data at extremely high bandwidths. The metallic conductors and waveguides stretching between the ambient and cryogenic environments in the related art offer an available data bandwidth insufficient for these high-performance superconducting devices.

Various embodiments of the invention include photonic/optical links for power supply into and data transmission into and out of a cryogenic environment, such as, but not limited to, 4° Kelvin or 77° Kelvin. This solves the problem of the limited heat capacity of cryogenic coolers and the extremely high bandwidth of data output from certain superconducting devices operating inside the cryogenic coolers. Thus, the overall performance improves from the reduction of some combination of size, weight, and power of the cryogenic system.

By switching the power delivery from thin metal wires to optical fiber, and by efficiently converting light carried by the optical fiber into electrical power within the cryogenic environment, heat leakage is significantly reduced because optical fibers have much lower thermal conduction than metal wires and because resistive losses are eliminated.

By switching data transfer from thin metal wires to optical fiber, heat leakage is further significantly reduced and the available data bandwidth is increased to the extremely high bandwidth offered from telecommunications through optical fiber. Even though telecommunication transceivers of the related art are generally designed for operation at an ambient temperature, these telecommunication transceivers not only properly operate in the cryogenic environment, but the properly operate in the cryogenic environment with higher performance and efficiency.

Switching to optical fiber offers further advantages. The elimination of connecting metal wires provides electrical isolation between the cryogenic electronics and the ambient environment. This eliminates the undesirable effects on the cryogenic electronics from electromagnetic noise in ambient environment coupling through electrical wires to the cryogenic electronics. The elimination of connecting metal wires prevents electromagnetic crosstalk between the optical channels for power delivery and data transfer.

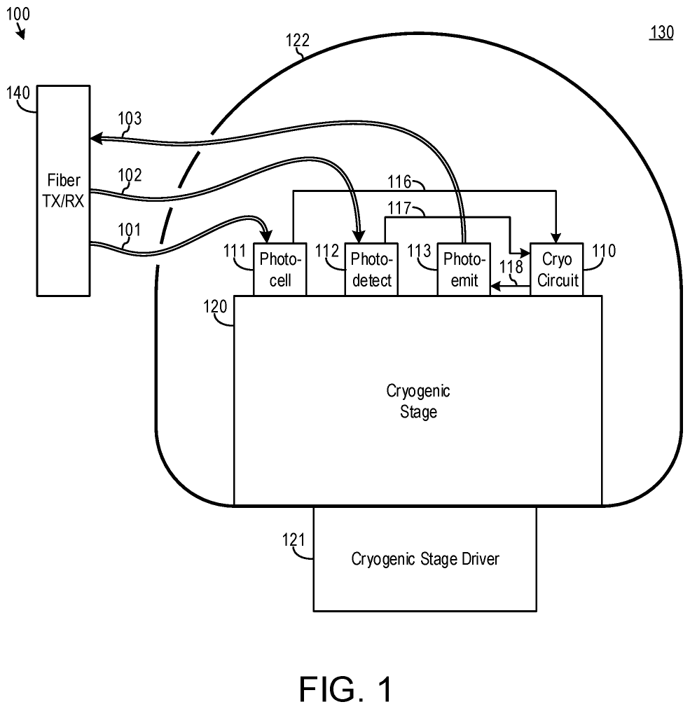

FIG. 1 is a block diagram of a cryogenic system 100 with optical fibers 101, 102, and 103 delivering power and transferring data in accordance with an embodiment of the invention. The cryogenic system 100 cools and operates cryogenic electronics including cryogenic circuit 110.

The cryogenic system 100 includes cryogenic stage 120 with cryogenic driver 121 for cooling the cryogenic electronics to an operational cryogenic temperature. The cryogenic stage 120 transfers heat from the cryogenic electronics to an ambient environment 130. The cryogenic system 100 includes an insulating enclosure 122 containing the cryogenic electronics and surrounded by the ambient environment 130, which is at room temperature or another ambient temperature.

The optical fibers 101, 102, and 103 deliver operational power from the ambient environment 130 to the cryogenic electronics and transfer communication data between the cryogenic electronics and the ambient environment 130. In the embodiment of FIG. 1, the optical fibers include optical fiber 101 for delivering operational power from the ambient environment 130 to the cryogenic electronics, optical fiber 102 for half-duplex transferring communication data from the ambient environment 130 to the cryogenic electronics, and optical fiber 103 for half-duplex transferring communication data from the cryogenic electronics to the ambient environment 130.

The optical fibers 101, 102, and 103 are the only connections delivering any power from the ambient environment 130 to the cryogenic electronics or transferring any data from the cryogenic electronics to the ambient environment 130. Hence, the cryogenic system 100 does not include any electrically conductive wires spanning between the ambient environment 130 at room temperature and the cryogenic electronics including cryogenic circuit 110. In particular, the cryogenic system 100 has no electrically conductive wires passing from the ambient environment 130 into the insulating enclosure 122.

The cryogenic electronics include a photocell 111 for converting light from fiber transceiver 140 via optical fiber 101 into electrical power on line 116 for powering the cryogenic electronics including cryogenic circuit 110. This incoming light delivers the operational power from the ambient environment 130 through the optical fiber 101 to the cryogenic electronics for powering the cryogenic circuit 110 and optionally powering a photodetector 112 and a photoemitter 113.

The cryogenic electronics include a photodetector 112 for converting light from fiber transceiver 140 via optical fiber 102 into an electrical signal on line 117. This incoming light transfers an incoming portion of the communication data from the ambient environment 130 through the optical fiber 102 to the cryogenic electronics. The electrical signal on line 117 carries the incoming portion of the communication data within the cryogenic electronics inside the insulating enclosure 122.

The cryogenic electronics include a photoemitter 113 for converting an electrical signal on line 118 into outgoing light delivered to fiber transceiver 140 via optical fiber 103. The electrical signal on line 118 carries an outgoing portion of the communication data within the cryogenic electronics inside the insulating enclosure 122. This outgoing light transfers the outgoing portion of the communication data from the cryogenic electronics inside the insulating enclosure 122 through the optical fiber 103 to the ambient environment 130.

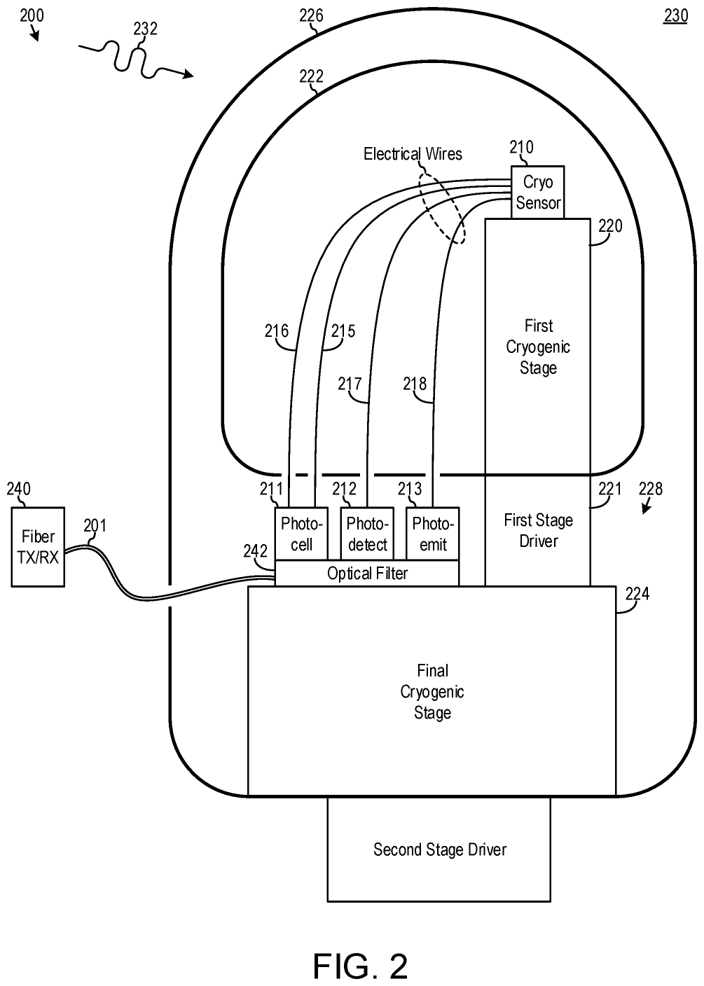

FIG. 2 is a block diagram of a cryogenic system 200 with an optical fiber 201 delivering power and transferring data in accordance with an embodiment of the invention. The optical fiber 201 transfers light, and this light includes a first incoming light, a second incoming light, and an outgoing light.

The cryogenic system 200 includes a first cryogenic stage 220 with an insulating enclosure 222 and a final cryogenic stage 224 with an insulating enclosure 226. The first cryogenic stage 220 transfers the heat from the cryogenic sensor 210 at the operational cryogenic temperature to a platform 228 at an intermediate cryogenic temperature. The final cryogenic stage 224 transfers the heat from the platform 228 at the intermediate cryogenic temperature to the ambient environment 230 at room temperature or another ambient temperature. Thus, cryogenic system 200 includes an insulating enclosure 226 containing the cryogenic electronics (cryogenic sensor 210, photocell 211, photodetector 212, and photoemitter 213) and surrounded by the ambient environment 230 at room temperature. The platform 228 at the intermediate cryogenic temperature includes a cryogenic driver 221 for the first cryogenic stage 220, the photocell 211, the photodetector 212, and the photoemitter 213 of the cryogenic electronics. It will be appreciated that there are more than two cryogenic stages arranged in series and/or parallel in other embodiments.

The photocell 211 converts the first incoming light into electrical power for powering the cryogenic electronics including the cryogenic sensor 210 and optionally a photodetector 212 and a photoemitter 213. The first incoming light delivers the operational power from the fiber transceiver 240 in the ambient environment 230 through the optical fiber 201 to the cryogenic electronics. The photocell 211 delivers the converted electrical power from the platform 228 to the cryogenic sensor 210 via electrical wires 215 and 216. In this embodiment, the electrical wire 216 supplies a positive supply voltage to the cryogenic sensor 210 and the electrical wire 215 supplies a ground to the cryogenic sensor 210 (the ground of electrical wire 215 is shared as the ground reference for electrical wires 217 and 218).

The cryogenic electronics include a photodetector 212 for converting the second incoming light into an incoming electrical signal that electrical wire 217 delivers to the cryogenic sensor 210. The second incoming light transfers an incoming portion of the communication data from the fiber transceiver 240 in the ambient environment 230 through the optical fiber 201 to the cryogenic electronics. The incoming electrical signal of electrical wire 217 carries the incoming portion of the communication data from the platform 228 to the cryogenic sensor 210.

The cryogenic electronics include a photoemitter 213 for converting an outgoing electrical signal carried on electrical wire 218 into the outgoing light. The outgoing electrical signal of electrical wire 218 carries an outgoing portion of the communication data from the cryogenic sensor 210 to the platform 228. The outgoing light transfers the outgoing portion of the communication data from the cryogenic electronics through the optical fiber 201 to the fiber transceiver 240 in the ambient environment 230. In another embodiment, electrical wire 218 is a balanced pair of electrical wires carrying a high-bandwidth differential signal from the cryogenic sensor 210 to the photoemitter 213.

The platform 228 includes an optical filter 242 that separates first, second, and third wavelength bands. The optical filter 242 passes the first incoming light within the first wavelength band from the optical fiber 201 to the photocell 211. The optical filter 242 passes the second incoming light within the second wavelength band from the optical fiber 201 to the photodetector 212. The optical filter 242 passes the outgoing light within the third wavelength band from the photoemitter 213 to the optical fiber 201. Because the optical filter 242 separates the first incoming light, the second incoming light, and the outgoing light based on wavelength, concurrently, the photocell 211 converts the first incoming light from the optical filter 242 into the electrical power for powering the cryogenic electronics via electrical wires 215 and 216, the photodetector 212 converts the second incoming light from the optical filter 242 into the incoming electrical signal of electrical wire 217, and the photoemitter 213 converts the outgoing electrical signal of electrical wire 218 into the outgoing light for the optical filter 242.

In another embodiment, instead of separating the first incoming light, the second incoming light, and the outgoing light based on wavelength, some or all of the first incoming light, the second incoming light, and the outgoing light are separated with time multiplexing through the optical fiber 201. For example, the optical filter 242 is a dichroic filter that passes visible wavelengths and reflects infrared wavelengths, with the optical filter 242 passing the visible wavelengths from the optical fiber 201 to the photocell 211, and with the optical filter 242 reflecting the infrared wavelengths from the optical fiber 201 to the photodetector 212 and reflecting the same infrared wavelengths from the photoemitter 213 to the optical fiber 201 for time multiplexing the infrared wavelengths through the optical fiber 201.

Although the cryogenic system 200 of FIG. 2 includes electrical wires 215, 216, 217, and 218 connecting and spanning between the platform 228 and the cryogenic sensor 210 of the cryogenic electronics, the only connection delivering any power from the ambient environment 230 to the cryogenic electronics (cryogenic sensor 210, photocell 211, photodetector 212, and photoemitter 213) or transferring any data from the cryogenic electronics to the ambient environment 230 is the optical fiber 201. Hence, the cryogenic system 200 does not include any electrically conductive wires spanning between the ambient environment 230 at room temperature and the cryogenic electronics.

The electrical wires 215, 216, 217, and 218 produce heat leakage between the platform 228 and the cryogenic sensor 210, and the first cryogenic stage 220 transfers this leaked heat back to the platform 228 (and the final cryogenic stage 224 transfers this leaked heat plus additional heat from cryogenic driver 221, the photocell 211, the photodetector 212, and the photoemitter 213 to the ambient environment 230).

However, in a preferred embodiment with cryogenic sensor 210 at 4° Kelvin, the total temperature difference between the cryogenic sensor 210 and the ambient environment 230 is nearly 300° Kelvin, but the temperature difference between the cryogenic sensor 210 and the platform 228 is less than 30° Kelvin. Because the heat leakage of the electrical wires 215, 216, 217, and 218 depends approximately linearly on the temperature difference between the ends of these wires inside and outside the insulating enclosure 222, the heat leakage of the electrical wires 215, 216, 217, and 218 across their 30° Kelvin temperature difference is about an order of magnitude less than the heat leakage that would occur with electrical wires spanning between the cryogenic sensor 210 and the ambient environment 230.

Because the electrical wires 215, 216, 217, and 218 spanning between the cryogenic sensor 210 and the platform 228 are shorter than would be electrical wires spanning between the cryogenic sensor 210 and the ambient environment 230, these short electrical wires 215, 216, 217, and 218 have less self-inductance and hence are capable of higher data bandwidth. Because the short electrical wires 215, 216, 217, and 218 are not connected into the ambient environment 230, these short electrical wires provide electrical isolation between the cryogenic electronics and the ambient environment 230. The short electrical wires 215, 216, 217, and 218 also reduce the electromagnetic crosstalk between the power delivery wires 215 and 216 and the data transfer wires 217 and 218.

Furthermore, in this preferred embodiment, the electrical wires 215, 216, 217, and 218 are superconducting electrical wires. In one example, the superconducting electrical wires 215, 216, 217, and 218 are composed of magnesium diboride, which is a superconductor with a critical temperature of 39° Kelvin. Thus, the electrical wires 215, 216, 217, and 218 of magnesium diboride are superconducting and do not incur any resistive losses from carrying electrical current between the platform 228 at less than 39° Kelvin and the cryogenic sensor 210. In another example, the superconducting electrical wires 215, 216, 217, and 218 are composed of Yttrium Boron Copper Oxide (YBCO) for the platform 228 at up to 90° Kelvin.

In summary, the short electrical wires 215, 216, 217, and 218 spanning between the cryogenic sensor 210 and the platform 228 help solve the related art's two problems of heat leakage through metallic conductors connecting the cryogenic and ambient environments, and the limited data bandwidth of such metallic conductors.

In the preferred embodiment, the photodetector 212 is a photodiode and the photoemitter 213 is a vertical cavity surface emitting laser (VCSEL). The cryogenic electronics include the cryogenic sensor 210, which senses an electrical field, a magnetic field, and/or an electromagnetic radiation that each originate outside the insulating enclosure 226, which contains the cryogenic electronics and is surrounded by the ambient environment 230 at room temperature or another ambient temperature. For example, the cryogenic sensor 210 senses the magnetic field of the electromagnetic radiation 232 propagating in the ambient environment 230 and through the transparent insulating enclosures 226 and 222. It will be appreciated that the electromagnetic radiation 232 encodes communication data, which cryogenic sensor 210 decodes and helps deliver to the ambient environment 230 via the electrical wire 218 and the optical fiber 201. In the preferred embodiment, the photodetector 212 and the electrical wire 217 are omitted unless the cryogenic sensor 210 has configuration registers requiring programming from the ambient environment 230.

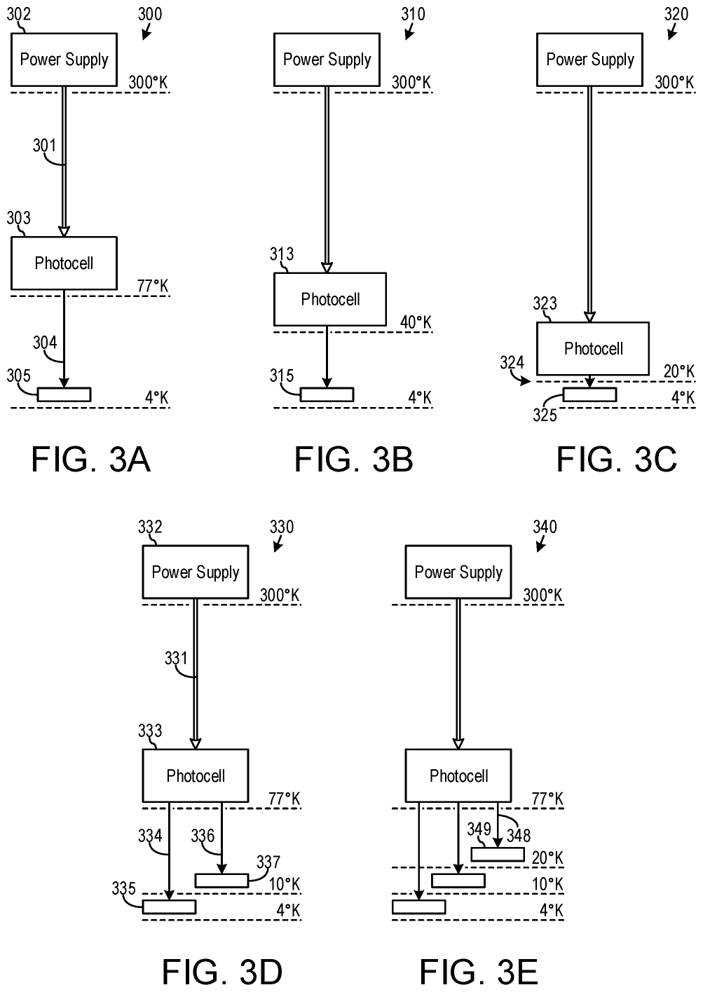

FIG. 3A-E are each a schematic diagram of a cryogenic system with an optical fiber and superconducting electrical wires delivering power in accordance with an embodiment of the invention.

In the cryogenic system 300 of FIG. 3A, an optical fiber 301 delivers operational power from the power supply 302 in the ambient environment at 300° K to the photocell 303 of a platform at an intermediate cryogenic temperature of 77° K. The photocell 303 of the cryogenic electronics converts light from the optical fiber 301 into electrical power for powering the cryogenic electronics. A superconducting electrical wire 304 delivers the electrical power from the platform to the cryogenic electronics 305 at the operational cryogenic temperature of 4° K. The superconducting electrical wire 304 has a critical temperature below 77° K because one end of the superconducting electrical wire 304 is at the intermediate cryogenic temperature of 77° K. For example, the superconducting electrical wire 304 is composed of Yttrium Boron Copper Oxide (YBCO). The superconducting electrical wire 304 eliminates resistive losses from carrying electrical current between the platform at of 77° K and cryogenic electronics 305 at 4° K.

The optical fiber 301 optionally also transfers communication data transferred between the cryogenic electronics 305 and the ambient environment at 300° K, and this communication data is transferred together with the electrical power over the superconducting electrical wire 304 or over additional superconducting wires as shown in FIG. 2. For example, the incoming light carried over the optical fiber 301 is modulated with an incoming portion of the communication data, the photocell 303 converts this modulation into an electrical current carried over the superconducting electrical wire 304, and the cryogenic electronics 305 recover the incoming communication data from the electrical current and also generate the electrical power with capacitive filtering that extracts the DC component of the electrical current. With sufficient capacitive filtering, time multiplexing also supports bursts of outgoing communication data transferred over the superconducting electrical wire 304 and the optical fiber 301.

The cryogenic system 310 of FIG. 3B and the cryogenic system 320 of FIG. 3C are similar to cryogenic system 300 of FIG. 3A, but the platform with the photocell 313 is at an intermediate cryogenic temperature of 40° K in FIG. 3B, and the platform with the photocell 323 is at an intermediate cryogenic temperature of 20° K in FIG. 3B. These lower intermediate cryogenic temperatures enable additional superconducting materials. For example, the superconducting electrical wire 324 of FIG. 3C is composed of magnesium diboride with a critical temperature of 39° K. In other embodiments, each of the cryogenic electronics 305 of FIG. 3A, the cryogenic electronics 315 of FIG. 3B, and the cryogenic electronics 325 of FIG. 3C is at an operational cryogenic temperature different from 4° K.

The cryogenic system 330 of FIG. 3D includes another cryogenic stage beyond the two cryogenic stages of FIG. 3A. A first cryogenic stage transfers heat from cryogenic electronics 335 at the operational cryogenic temperature of 4° K to a platform at an intermediate cryogenic temperature of 77° K. A second cryogenic stage transfers heat from the second cryogenic electronics 337 at the operational cryogenic temperature of 10° K to the platform at the intermediate cryogenic temperature of 77° K. A final cryogenic stage transfers heat, which includes heat from both the first and second cryogenic stages, from the platform at the intermediate cryogenic temperature of 77° K to the ambient environment at room temperature of 300° K.

An optical fiber 331 delivers operational power from the power supply 332 in the ambient environment at 300° K to the photocell 333 of the platform at the intermediate cryogenic temperature of 77° K. The photocell 333 of the cryogenic electronics converts light from the optical fiber 331 into electrical power for powering the cryogenic electronics. A first superconducting electrical wire 334 delivers a first portion of the electrical power from the platform at an intermediate cryogenic temperature of 77° K to the cryogenic electronics 335 at an operational cryogenic temperature of 4° K. A second superconducting electrical wire 336 delivers a second portion of the electrical power from the platform at an intermediate cryogenic temperature of 77° K to the cryogenic electronics 337 at an additional operational cryogenic temperature of 10° K. The optical fiber 331 and each of the superconducting electrical wires 334 and 336 optionally also transfer communication data, which is transferred between any combination of the ambient environment at 300° K and the cryogenic electronics 335 and 337.

The cryogenic system 340 of FIG. 3E is similar to cryogenic system 330 of FIG. 3D, but includes an additional cryogenic stage that transfers heat from cryogenic electronics 349 at yet another operational cryogenic temperature of 20° K. A third superconducting electrical wire 348 delivers a third portion of the electrical power from the platform at an intermediate cryogenic temperature of 77° K to the cryogenic electronics 349 at the operational cryogenic temperature of 20° K. It will be appreciated that the temperatures shown in FIG. 3A-E vary in other embodiments.

From the above description of A Cryogenic System with Optical Fiber Delivering Power and Transferring Data, it is manifest that various techniques may be used for implementing the concepts of cryogenic systems 100, 200, 300, 310, 320, 330, and 340 without departing from the scope of the claims. The described embodiments are to be considered in all respects as illustrative and not restrictive. The method/apparatus disclosed herein may be practiced in the absence of any element that is not specifically claimed and/or disclosed herein. It should also be understood that cryogenic system 100, 200, 300, 310, 320, 330, or 340 is not limited to the particular embodiments described herein, but is capable of many embodiments without departing from the scope of the claims.

We claim:

1. A cryogenic system for cooling and operating cryogenic electronics, the cryogenic system comprising:
at least one cryogenic stage for cooling the cryogenic electronics to at least one operational cryogenic temperature, the at least one cryogenic stage for transferring heat from the cryogenic electronics to an ambient environment; and
at least one optical fiber for delivering operational power from the ambient environment to the cryogenic electronics and for transferring communication data between the cryogenic electronics and the ambient environment.

2. The cryogenic system of claim 1, wherein the only connection delivering any power from the ambient environment to the cryogenic electronics or transferring any data from the cryogenic electronics to the ambient environment is the at least one optical fiber.

3. The cryogenic system of claim 1, wherein the cryogenic system does not include any electrically conductive wires spanning between the ambient environment at room temperature and the cryogenic electronics.

4. The cryogenic system of claim 1, further comprising:
an insulating enclosure containing the cryogenic electronics and surrounded by the ambient environment at room temperature,
wherein the only connection delivering any power from the ambient environment into the insulating enclosure or transferring any data out of the insulating enclosure is the at least one optical fiber, and
wherein no electrically conductive wires pass from the ambient environment into the insulating enclosure.

5. The cryogenic system of claim 1, wherein the cryogenic electronics include a photocell for converting light, which delivers the operational power from the ambient environment through the at least one optical fiber to the cryogenic electronics, into electrical power for powering the cryogenic electronics.

6. The cryogenic system of claim 1, wherein the cryogenic electronics include a photodetector for converting light, which transfers an incoming portion of the communication data from the ambient environment through the at least one optical fiber to the cryogenic electronics, into an electrical signal, which carries the incoming portion of the communication data within the cryogenic electronics.

7. The cryogenic system of claim 1, wherein the cryogenic electronics include a photoemitter for converting an electrical signal, which carries an outgoing portion of the communication data within the cryogenic electronics, into light, which transfers the outgoing portion of the communication data from the cryogenic electronics through the at least one optical fiber to the ambient environment.

8. The cryogenic system of claim 1, wherein:
the at least one optical fiber is an optical fiber transferring light, which includes a first and second incoming light and an outgoing light; and
the cryogenic electronics include:
a photocell for converting the first incoming light, which delivers the operational power from the ambient environment through the optical fiber to the cryogenic electronics, into electrical power for powering the cryogenic electronics;
a photodetector for converting the second incoming light, which transfers an incoming portion of the communication data from the ambient environment through the optical fiber to the cryogenic electronics, into an incoming electrical signal, which carries the incoming portion of the communication data within the cryogenic electronics; and
a photoemitter for converting an outgoing electrical signal, which carries an outgoing portion of the communication data within the cryogenic electronics, into the outgoing light, which transfers the outgoing portion of the communication data from the cryogenic electronics through the optical fiber to the ambient environment.

9. The cryogenic system of claim 8, wherein:
the cryogenic electronics include an optical filter for separating a first, second, and third wavelength band,
the optical filter passing the first incoming light within the first wavelength band from the optical fiber to the photocell,
the optical filter passing the second incoming light within the second wavelength band from the optical fiber to the photodetector, and
the optical filter passing the outgoing light within the third wavelength band from the photoemitter to the optical fiber.

10. The cryogenic system of claim 9, wherein concurrently:
the photocell converts the first incoming light from the optical filter into the electrical power for powering the cryogenic electronics,
the photodetector converts the second incoming light from the optical filter into the incoming electrical signal, and
the photoemitter converts the outgoing electrical signal into the outgoing light for the optical filter.

11. The cryogenic system of claim 10, wherein:
the only connection delivering any power from the ambient environment to the cryogenic electronics or transferring any data from the cryogenic electronics to the ambient environment is the optical fiber, and
the cryogenic system does not include any electrically conductive wires spanning between the ambient environment at room temperature and the cryogenic electronics.

12. The cryogenic system of claim 10, wherein the photodetector is a photodiode and the photoemitter is a vertical cavity surface emitting laser (VCSEL), and wherein the cryogenic electronics further include a sensor that senses an electrical field, a magnetic field, and/or an electromagnetic radiation that each originate outside an insulating enclosure, which contains the cryogenic electronics and is surrounded by the ambient environment at room temperature.

13. The cryogenic system of claim 1, wherein at least one cryogenic stage includes a first and final cryogenic stage, the first cryogenic stage for transferring the heat from the cryogenic electronics at the operational cryogenic temperature to a platform at an intermediate cryogenic temperature, and the final cryogenic stage for transferring the heat from the platform at the intermediate cryogenic temperature to the ambient environment at room temperature.

14. The cryogenic system of claim 13, wherein the platform at the intermediate cryogenic temperature includes:
a photocell of the cryogenic electronics for converting an incoming light into electrical power for powering the cryogenic electronics, the incoming light delivering the operational power from the ambient environment through the optical fiber to the platform; and
at least one superconducting electrical wire for delivering the electrical power from the platform to the cryogenic electronics at the operational cryogenic temperature.

15. The cryogenic system of claim 13, wherein:
the at least one optical fiber is an optical fiber transferring light, which includes a first and second incoming light and an outgoing light; and
the platform at the intermediate cryogenic temperature includes:
a photocell of the cryogenic electronics for converting the first incoming light, which delivers the operational power from the ambient environment through the optical fiber to the platform, into electrical power for powering the cryogenic electronics;
a photodetector of the cryogenic electronics for converting the second incoming light, which transfers an incoming portion of the communication data from the ambient environment through the optical fiber to the platform, into an incoming electrical signal, which carries the incoming portion of the communication data from the platform to the cryogenic electronics; and
a photoemitter of the cryogenic electronics for converting an outgoing electrical signal, which carries an outgoing portion of the communication data from the cryogenic electronics to the platform, into the outgoing light, which transfers the outgoing portion of the communication data from the platform through the optical fiber to the ambient environment.

16. The cryogenic system of claim 15, wherein:
the platform includes a first, second, and third electrically conductive wire,
the first electrically conductive wire for delivering the electrical power from the platform to the cryogenic electronics,
the second electrically conductive wire for carrying the incoming portion of the communication data from the platform to the cryogenic electronics, and
the third electrically conductive wire for carrying the outgoing portion of the communication data from the cryogenic electronics to the platform.

17. The cryogenic system of claim 16, wherein the cryogenic system does not include any electrically conductive wires spanning between the ambient environment at room temperature and the cryogenic electronics.

18. The cryogenic system of claim 16, wherein:
the platform includes an optical filter for separating a first, second, and third wavelength band,
the optical filter passing the first incoming light within the first wavelength band from the optical fiber to the photocell,
the optical filter passing the second incoming light within the second wavelength band from the optical fiber to the photodetector, and
the optical filter passing the outgoing light within the third wavelength band from the photoemitter to the optical fiber;
and wherein concurrently:
the photocell converts the first incoming light from the optical filter into the electrical power, which the first electrically conductive wire, which is a first superconducting electrical wire, delivers from the platform to the cryogenic electronics,
the photodetector converts the second incoming light from the optical filter into the incoming electrical signal, wherein the second electrically conductive wire, which is a second superconducting electrical wire, carries the incoming electrical signal carrying the incoming portion of the communication data from the platform to the cryogenic electronics, and
the photoemitter converts the outgoing electrical signal into the outgoing light for the optical filter, wherein the third electrically conductive wire, which is a third superconducting electrical wire, carries the outgoing electrical signal carrying the outgoing portion of the communication data from the cryogenic electronics to the platform.

19. The cryogenic system of claim 1, wherein:
the at least one cryogenic stage includes at least a first and second cryogenic stage and a final cryogenic stage;
the cryogenic electronics includes at least a first cryogenic electronics and a second cryogenic electronics;
the at least one operational cryogenic temperature includes at least a first operational cryogenic temperature and a second operational cryogenic temperature that differ;
the heat includes at least a first heat and a second heat;
the first cryogenic stage for transferring the first heat from the first cryogenic electronics at the first operational cryogenic temperature to a platform at an intermediate cryogenic temperature;
the second cryogenic stage for transferring the second heat from the second cryogenic electronics at the second operational cryogenic temperature to the platform at the intermediate cryogenic temperature; and
the final cryogenic stage for transferring the heat, which includes the first heat and the second heat, from the platform at the intermediate cryogenic temperature to the ambient environment at room temperature.

20. The cryogenic system of claim 19, wherein the platform at the intermediate cryogenic temperature includes:
a photocell of the cryogenic electronics for converting an incoming light into electrical power for powering the cryogenic electronics, the incoming light delivering the operational power from the ambient environment through the optical fiber to the platform;
a first superconducting electrical wire for delivering a first portion of the electrical power from the platform to the first cryogenic electronics at the first operational cryogenic temperature; and
a second superconducting electrical wire for delivering a second portion of the electrical power from the platform to the second cryogenic electronics at the second operational cryogenic temperature.
